(19) United States
(12) Patent Application Publication
(10) Pub. No.: US 2009/0289370 A1
(43) Pub. Date: Nov. 26, 2009

(54) LOW CONTACT RESISTANCE SEMICONDUCTOR DEVICES AND METHODS FOR FABRICATING THE SAME

(75) Inventors: Paul R. BESSER, Sunnyvale, CA (US); Andreas H. KNORR, Wappingers Falls, NY (US)

Correspondence Address: INGRASSIA FISHER & LORENZ, P.C. (AMD), 7010 E. COCHISE ROAD, SCOTTSDALE, AZ, 85253, US

(73) Assignee: ADVANCED MICRO DEVICES, INC., Austin, TX (US)

(21) Appl. No.: 12/124,879

(22) Filed: May 21, 2008

(51) Int. Cl. H01L 23/48; H01L 21/44; H01L 21/336

(52) U.S. Cl. 257/768; 438/675; 438/301; 257/E21.476; 257/E21.409; 257/E23.01

(57) ABSTRACT

Low contact resistance semiconductor devices and methods for fabricating such semiconductor devices are provided. In accordance with one exemplary embodiment, a method comprises depositing an insulating material overlying a metal silicide region and etching a contact opening within the insulating material and exposing the metal silicide region. The contact opening is at least partially bottom-filled with substantially pure cobalt. A conductor is deposited in the contact opening if, after the step of at least partially bottom-filling, the contact opening is not filled with the substantially pure cobalt.

### FIELD OF THE INVENTION

The present invention generally relates to integrated circuits and methods for fabricating integrated circuits, and more particularly relates to low contact resistance semiconductor devices and to methods for their fabrication.

### BACKGROUND OF THE INVENTION

The majority of present day integrated circuits (ICs) are implemented by using a plurality of interconnected field effect transistors (FETs), also called metal oxide semiconductor field effect transistors (MOSFETs or MOS transistors). The ICs are usually formed using both P-channel and N-channel FETs and the IC is then referred to as a complementary MOS or CMOS integrated circuit (IC). There is a continuing trend to incorporate more and more circuitry on a single IC chip. To incorporate the increasing amount of circuitry, the size of each individual device in the circuit and the size and spacing between device elements (the feature size) must decrease.

The individual elements of the circuits, including MOS transistors and other passive and active circuit elements, must be interconnected by metal or other conductors to implement a desired circuit function. Some small resistance is associated with each contact between the conductor and the circuit element and within the conductor itself. As the feature size decreases, the contact resistance increases and becomes a greater and greater percentage of the total circuit resistance. As feature sizes decrease from 150 nanometer (nm) to 90 nm, then to 45 nm and below, the contact resistance becomes more and more important. At feature sizes of 32 nm, the contact resistance likely will dominate chip performance unless some innovation changes the present trend.

Contact to a circuit element, such as an MOS transistor, typically is formed by etching a contact opening in an insulating material overlying the circuit element and filling the contact opening with a conductive metal plug of, for example, tungsten or copper. A conductive interconnect then is formed overlying the insulating material and electrically coupled to the contact plug. Presently, tungsten and copper both create challenges to fabrication of low resistance contact plugs. Tungsten typically creates high resistance in contacts with high aspect ratios. While copper exhibits lower resistance in small contacts, it has a high affinity for silicon and, thus, requires that a barrier layer be deposited within the contact opening before the copper is deposited therein. However, as the barrier layer typically is very thin, on the order of less than 10 nm, difficulties arise with the formation of a barrier layer having suitable integrity. In addition, the deposition of copper within contact openings without the creation of voids is challenging. The presence of voids within the copper contact can increase the resistance of the contact and adversely affect the electrical characteristics of the resulting device.

Accordingly, it is desirable to provide low contact resistance semiconductor devices. In addition, it is desirable to provide methods for fabricating low contact resistance semiconductor devices. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

Low contact resistance semiconductor devices and methods for fabricating such semiconductor devices are provided in accordance with exemplary embodiments of the present invention. In accordance with one exemplary embodiment, a method comprises depositing an insulating material overlying a metal silicide region and etching a contact opening within the insulating material and exposing the metal silicide region. The contact opening is at least partially bottom-filled with substantially pure cobalt. A conductor is deposited in the contact opening if, after the step of at least partially bottom-filling, the contact opening is not filled with the substantially pure cobalt.

A method for fabricating an MOS device is provided in accordance with another exemplary embodiment. The method comprises forming a gate electrode overlying a surface of a silicon substrate, forming impurity-doped source and drain regions at the surface of the silicon substrate in alignment with the gate electrode, and forming metal silicide regions overlying the impurity-doped source and drain regions. An insulating material is deposited overlying the gate electrode and the metal silicide regions and contact openings are etched within the insulating material and expose the metal silicide regions. Substantially pure cobalt is deposited to partially fill the contact openings and a conductor is deposited in the contact openings overlying the substantially pure cobalt.

A semiconductor device is provided in accordance with an exemplary embodiment of the invention. The semiconductor device comprises an impurity-doped region disposed at a surface of a semiconductor substrate, a metal silicide disposed on the impurity-doped region, an insulating material overlying the impurity-doped region and having a contact opening exposing the metal silicide, and a substantially pure cobalt portion. The substantially pure cobalt portion at least partially bottom fills the contact opening.

### BRIEF DESCRIPTION OF THE DRAWINGS

The present invention will hereinafter be described in conjunction with the following drawing figures, wherein like numerals denote like elements, and wherein:

FIGS. 1-4 illustrate, in cross-section, a method for fabricating a MOS transistor device in accordance with an exemplary embodiment of the present invention; and

FIG. 5 is a graph illustrating the change of the estimated resistances of various contact materials as contact dimension decreases.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

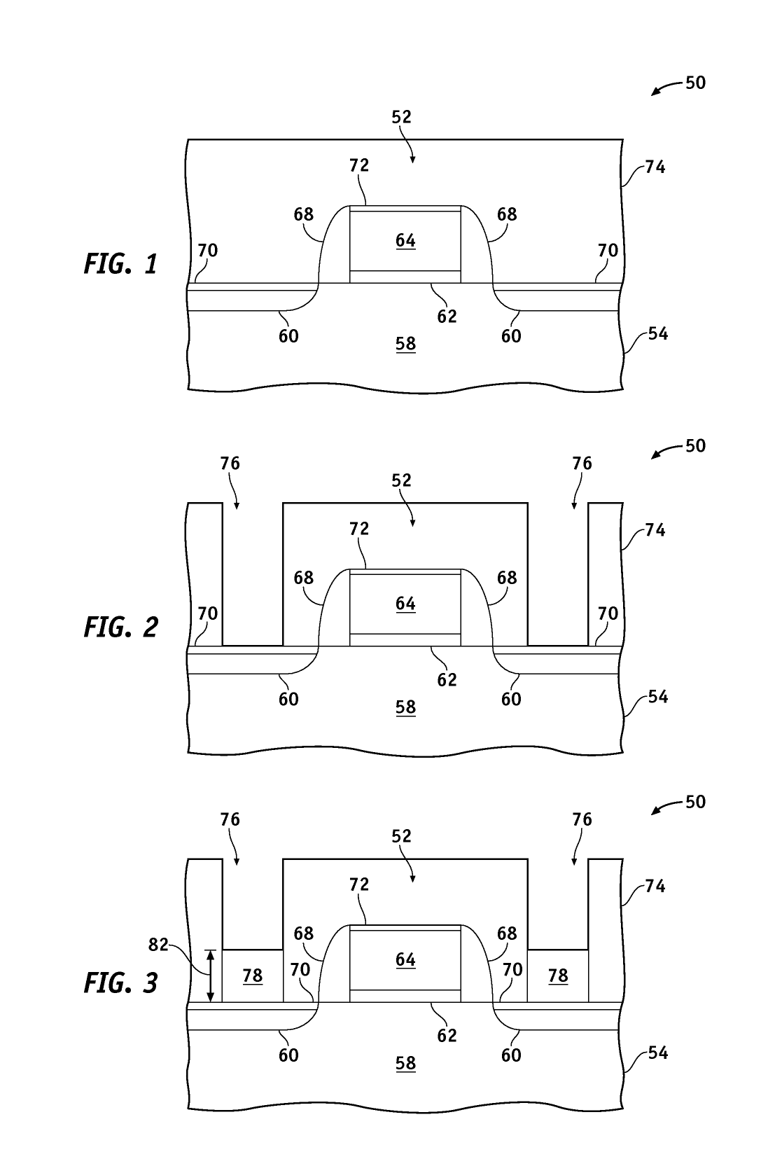

FIGS. 1-4 schematically illustrate, in cross section, a semiconductor device 50 and method steps for the fabrication of a semiconductor device 50, in accordance with various embodiments of the present invention. Semiconductor device 50 may be a diode, a bipolar transistor, a microelectrical mechanical system (MEMS), an MOS device, or the like. For purposes of illustration, FIGS. 1-4 illustrate semiconductor device 50 as an MOS device. Various steps in the manufacture of MOS components are well known and so, in the interest of brevity, many conventional steps will only be mentioned briefly herein or will be omitted entirely without providing the well known process details. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

Referring to FIG. 1, MOS device 50 includes a plurality of MOS transistors 52, which can be N-channel or P-channel MOS transistors or a combination of the two transistors. While only one MOS transistor 52 is illustrated in FIG. 1, those of skill in the art will appreciate that MOS device 50 may include a large number of such transistors as required to implement a desired circuit function. The initial steps in the fabrication of MOS device 50 are conventional so the structure resulting from these steps is illustrated in FIG. 1, but the initial steps themselves are not shown. The MOS transistor 52 is fabricated on a silicon substrate 54, which can be either a bulk silicon wafer as illustrated or a thin silicon layer on an insulating substrate (SOI). As used herein, the terms “silicon layer” and “silicon substrate” will be used to encompass the relatively pure or lightly impurity-doped monocrystalline silicon materials typically used in the semiconductor industry as well as silicon admixed with other elements such as germanium, carbon, and the like to form substantially monocrystalline semiconductor material. At least a surface portion 58 of the silicon substrate is doped with P-type conductivity-determining impurities for the fabrication of an N-channel MOS transistor or with N-type conductivity-determining impurities for the fabrication of P-channel MOS transistors. Portion 58 can be impurity doped, for example, by the implantation and subsequent thermal annealing of dopant ions such as boron and arsenic.

In the conventional processing, a layer of gate insulating material 62 is formed at the surface of the impurity doped region 58 and a gate electrode 64 is formed overlying the gate insulating material and impurity doped region 58. The layer of gate insulating material can be a layer of thermally grown silicon dioxide or, alternatively (as illustrated), a deposited insulator such as a silicon oxide, silicon nitride, a high dielectric constant insulator such as hafnium silicate (HfSiOₓ, where x is greater than zero) or the like. Deposited insulators can be deposited, for example, by chemical vapor deposition (CVD), low pressure chemical vapor deposition (LPCVD), or plasma enhanced chemical vapor deposition (PECVD). Gate insulator 62 preferably has a thickness of about 1-10 nm, although the actual thickness can be determined based on the application of the transistor in the circuit being implemented. Gate electrode 64 comprises an electrically conductive material, such as a metal or metal alloy, or a material that can be made electrically conductive and is preferably formed by depositing, patterning, and etching a layer of polycrystalline silicon, preferably a layer of undoped polycrystalline silicon. The gate electrode generally has a thickness of about 50-300 nm. The polycrystalline silicon can be deposited, for example, by the reduction of silane in a CVD reaction. Sidewall spacers 68 are formed on the sidewalls of gate electrode 64. The sidewall spacers are formed by depositing a layer of insulating material such as silicon oxide and/or silicon nitride and subsequently anisotropically etching the insulating layer, for example by reactive ion etching (RIE). Silicon oxide and silicon nitride can be etched, for example, in a CHF₃, CF₄, or SF₆ chemistry. Conductivity-determining ions are implanted into the silicon substrate 54 to form source and drain regions 60. If portion 58 of the silicon substrate 54 is P-type, N-type conductivity-determining ions are implanted to form N-type source and drain regions in the silicon substrate and to conductivity dope the gate electrode 64 with N-type impurities. The implanted ions can be, for example, either phosphorus or arsenic ions. Alternatively, if portion 58 of the silicon substrate 54 is N-type, P-type conductivity-determining ions are implanted to form P-type source and drain regions in the silicon substrate and to conductivity dope the gate electrode with P-type impurities. The implanted ions can be, for example, boron. The ion implanted source and drain regions 60 are self aligned with the gate electrode 64. As those of skill in the art will appreciate, additional sidewall spacers and additional implantations may be employed to create drain extensions, halo implants, deep source and drains, and the like.

In accordance with an embodiment of the invention, a layer of silicide-forming metal (not shown) is deposited over the structure and in contact with the source and drain regions 60 and gate electrode 64. Examples of suitable silicide-forming metals include, but are not limited to, nickel, cobalt, and alloys thereof. The silicide-forming metal can be deposited, for example by sputtering, to a thickness of about 4-50 nm and preferably to a thickness of about 10 nm. In accordance with one embodiment of the invention, the structure with the silicide-forming metal is heated, for example by RTA, to cause the silicide-forming metal to react with exposed silicon to form a metal silicide 70 at the surface of the source and drain regions 60 and a metal silicide 72 on the gate electrode 64. The silicide forms only in those areas where there is exposed silicon. Silicide does not form, and the silicide forming metal remains unreacted, in those areas where there is no exposed silicon, such as on the sidewall spacers. The unreacted silicide-forming metal can be removed by wet etching in a H₂O₂/H₂SO₄ or HNO₃/HCl solution. After the formation of metal silicides 70 and 72, a layer 74 of dielectric material such as a layer of silicon oxide is deposited overlying MOS device 50. Layer 74 is preferably deposited by a low temperature process and may be deposited, for example by a LPCVD process. Although not illustrated, layer 74 may include layers of more than one dielectric material, and those layers may include, for example, an etch stop layer to facilitate the subsequent etching of the vias.

Referring to FIG. 2, the top surface of layer 74 is planarized, for example by chemical mechanical planarization (CMP), and openings or vias 76 are etched through the layer to expose portions of metal silicide regions 70. In this illustrative embodiment, no vias are shown that expose portions of the metal silicide 72 on gate electrode 64. Depending on the circuit being implemented, however, vias may or may not be formed to the gate electrode.

After formation of vias 76, substantially pure cobalt is electrolessly deposited within the vias to form cobalt portions 78, as illustrated in FIG. 3. Prior to the deposition of cobalt portions 78, a suitable pre-cleaning process such as, for example, treatment with diluted hydrofluoric acid may be used to remove any surface oxide on the exposed metal silicide regions 70 to enhance cobalt nucleation and growth. As used herein, the term “substantially pure cobalt” means cobalt that has no more than trace amounts of impurities such as, for example, boron, phosphorous, and oxygen, that do not increase the resistance of the cobalt portion 78 by more than 10%. In one exemplary embodiment, “substantially pure cobalt” means cobalt having no more than 2% impurities. In preferred exemplary embodiment, “substantially pure cobalt” means cobalt having no more than 1% impurities. Deposition of substantially pure cobalt in the vias serves to minimize the resistance of the resulting cobalt portions 78. In one exemplary embodiment (not shown), the vias are completely filled with the cobalt portions and any overfill is removed by, for example, CMP. In another, preferred embodiment, the vias are partially filled with cobalt such that the aspect ratio of the via is reduced, thereby reducing the resistance of a subsequently-formed contact plug, which, as discussed in more detail below, fills the remainder of the via. As used herein, the term “partially filled” means that more than 0% but less than 100% of the via is filled. The cobalt portion also overcomes other contact fill challenges. For example, the cobalt portions prevent both the migration of plug material or plug material-forming reactants into the silicon and the migration of silicon into the plug material. In this regard, the migration decreases as the thickness, indicated by double-headed arrow 82, of the cobalt portion 78 increases. Cobalt also does not readily react with metal silicides 70, particularly nickel silicide. In addition, the electroless deposition of cobalt within the vias accomplishes back-fill deposition with a minimal number of voids compared to the back-fill deposition of copper or tungsten, thus decreasing the total number of voids in the overall contact.

The cobalt can be electrolessly deposited by exposing the MOS device 50 to a suitable electroless deposition solution. Electroless deposition solutions for cobalt deposition are well known. Electroless deposition solutions can be formulated using, for example, a source of cobalt ions, a reducing agent, and a complexing agent and/or a chelating agent. Examples of sources of cobalt ions for use in the electroless deposition solution include inorganic cobalt salts such as the hydroxide, chloride, sulfate, or other suitable inorganic salts, or a cobalt complex with an organic carboxylic acid such as cobalt acetate, citrate, lactate, succinate, propionate, hydroxyacetate, or others. In one embodiment, the cobalt salt or complex is added to provide about 1 g/L to about 20 g/L of Co²⁺ to yield a high cobalt metal content. Suitable reducing agents include dimethyl amine borane (DMAB) and hydrazine.

The electroless deposition solution further may contain buffering agents. The solution typically contains a pH buffer to stabilize the pH in a desired range. In one embodiment, the desired pH range is between about 7.5 and about 10.0. Exemplary buffers include, for example, borates, tetra- and pentaborates, phosphates, acetates, glycolates, lactates, ammonia, and pyrophosphate.

A complexing and/or chelating agent may be included in the electroless deposition solution to keep cobalt ions in solution. Because the bath is typically operated at a mildly alkaline pH of between about 7.5 and about 10.0, Co²⁺ ions have a tendency to form hydroxide salts and precipitate out of solution. The complexing agents used in the bath may be selected from among citric acid, malic acid, glycine, propionic acid, succinic acid, lactic acid, DEA, TEA, and ammonium salts such as ammonium chloride, ammonium sulfate, ammonium hydroxide, pyrophosphate, and mixtures thereof. The complexing agent concentration is selected such that the molar ratio between the complexing agent and cobalt is between about 2:1 and about 10:1, generally. Depending on the complexing agent molecular weight, the level of complexing agent may be on the order of between about 10 g/L and about 120 g/L. The electroless deposition solution also may contain a variety of other components, such as surfactants, accelerators, suppressors, levelers, grain refiners, and the like.

The electroless deposition process occurs with the electroless deposition solution at a temperature in the range of about 20° C. to about 100° C., and preferably at a temperature of about 40° C. to about 70° C. If the deposition temperature is too low, the reduction rate is too low to be commercially practical, and at a low enough temperature, cobalt reduction does not initiate at all. At too high a temperature, the deposition rate increases, and the bath becomes too active. For example, cobalt reduction becomes less selective, and cobalt plating may occur not just on the metal silicide 70, but also on the dielectric material 74. Further, at very high temperatures, cobalt reduction occurs spontaneously within the electroless deposition solution and on the sidewalls of the deposition tank.

The MOS device 50 is exposed to the electroless deposition solution for a time sufficient to permit a desired amount of cobalt to back fill the via. This exposure may comprise dip, flood immersion, spray, or other manner of exposing the MOS device 50 to the electroless deposition solution, with the provision that the manner of exposure adequately achieves the objectives of depositing a cobalt portion 78 of the desired thickness and integrity. In accordance with one exemplary embodiment, the electroless deposition solution may be used in conventional continuous mode deposition processes. In the continuous mode, the same solution volume is used to treat a large number of substrates. In this mode, reactants must be periodically replenished, and reaction products accumulate, necessitating periodic filtering of the deposition solution. In an alternative embodiment, the electroless deposition solution may be used in so-called “use-and-dispose” deposition processes. In the use-and-dispose mode, the deposition solution is used to treat a substrate, and then the solution is directed to a waste. Although this latter method may be more expensive, the use-and-dispose mode requires no metrology, that is, measuring and adjusting the solution composition to maintain deposition solution stability is not required.

After deposition of the cobalt portions 78, a conductive barrier layer 80 is deposited in the vias in contact with the cobalt portions, as illustrated in FIG. 4. The conductive barrier layer acts as a barrier to the migration of plug materials subsequently deposited into the vias 76. Suitable materials for the conductive barrier layer include, for example tantalum (Ta) and tantalum nitride (TaN) or layers of both, such as for use with a copper (Cu) plug, and titanium and titanium nitride (TiN) or layers of both, such as for use with a tungsten (W) plug. The conductive barrier layer can be deposited, for example, by LPCVD, atomic layer deposition (ALD), or physical vapor deposition (PVD). TiN and TaN can also be formed by deposition and subsequent nitridation of titanium or tantalum, respectively. The barrier layer preferably has a thickness as measured from the surface of the cobalt portion 78 of about 1-5 nm. The thickness is preferably adjusted to minimize the resistance of the barrier layer while maintaining sufficient thickness to achieve the appropriate barrier qualities. As also illustrated in FIG. 4, once the barrier metal layer is deposited, the vias can be filled by depositing conductive plugs 82 of tungsten, copper, or other conductive material to form conductive contacts 90. Preferably the conductive plug material is copper to reduce the resistance of the resulting contacts 90. The conductive material can be deposited, for example, by PVD, ALD, CVD, or electrochemical means. An optional seed layer (not shown) may be deposited overlying the barrier layer before deposition of the conductive plugs. Any overfill of the barrier layer, seed layer, and/or the conductive plug material can be removed by, for example, CMP.

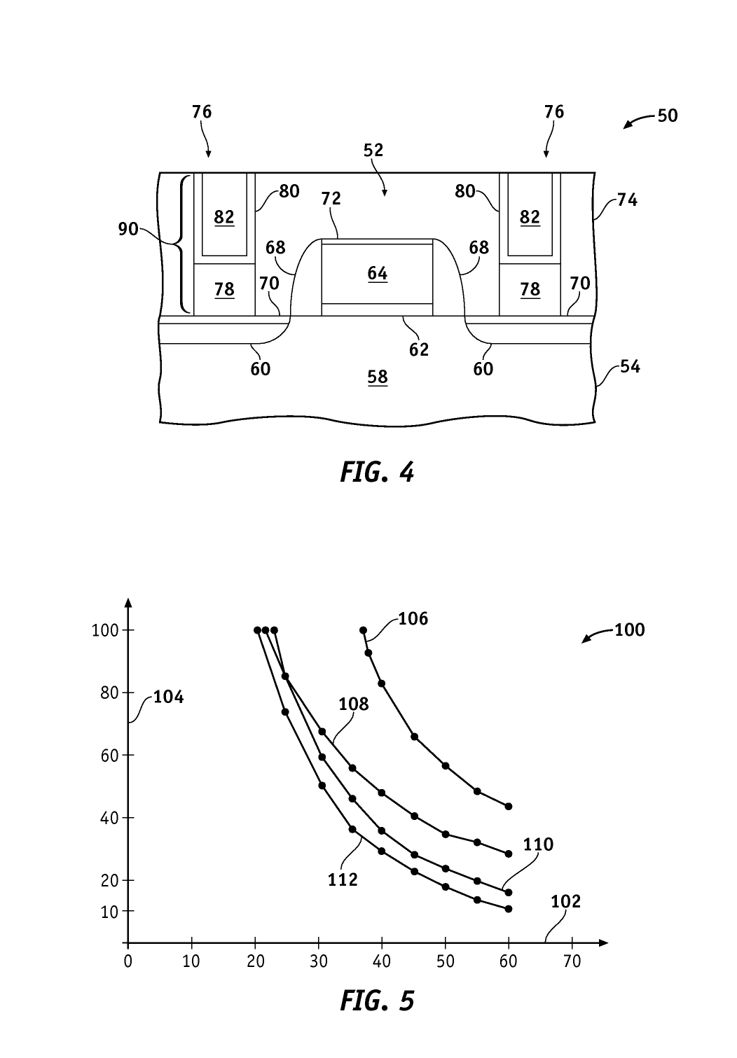

FIG. 5 is a graph 100 illustrating the differences of estimated resistance between various contacts 90. The horizontal or x-axis 102 represents the critical dimension, that is, the diameter of the contact in nanometers and the vertical or y-axis 104 illustrates the resistance of the contact in ohms. Curve 106 represents the resistance of a contact 90 fabricated entirely of tungsten. As can be seen, the estimated resistance of the tungsten contact increases exponentially as the contact size decreases and prohibits the scaling of tungsten contacts to sizes as small as 20 nm. On the other hand, the estimated resistance of copper, represented by curve 112, is far below that of tungsten and is scalable to dimensions of 20 nm and less. The resistance of cobalt, illustrated by curve 108, is lower than that of tungsten but is higher than that of copper. However, a contact 90 partially filled with cobalt with the remainder filled with copper, illustrated by curve 110, demonstrates a resistance close to that of copper. This is due not only to the low resistance of cobalt, but also due to the decrease in the aspect ratio of the contact via 76 after the cobalt portion is deposited. Thus, a lower resistance contact that overcomes the challenges faced with low resistance copper contacts can be realized. For example, as noted above, the cobalt portions prevent both the migration of plug material or plug material-forming reactants into the silicon and the migration of silicon into the plug material. In this regard, diffusion decreases as the thickness of the cobalt portion increases. In addition, cobalt does not react readily with the metal silicide 70, particularly nickel silicide. Further, electroless deposition of cobalt can be performed with a minimal number of voids, thus decreasing the overall number of voids of the entire contact 90.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims and their legal equivalents.

What is claimed is:

1. A method for fabricating a semiconductor device, the method comprising the steps of:
depositing an insulating material overlying a metal silicide region;
etching a contact opening within the insulating material and exposing the metal silicide region;
at least partially bottom-filling the contact opening with substantially pure cobalt; and
depositing a conductor in the contact opening if, after the step of at least partially bottom-filling, the contact opening is not filled with the substantially pure cobalt.

2. The method of claim 1, wherein the step of depositing a conductor comprises depositing copper.

3. The method of claim 1, wherein the step of depositing a conductor comprises depositing tungsten.

4. The method of claim 1, further comprising the step of depositing a barrier layer within the contact opening after the step of at least partially bottom-filling and before the step of depositing a conductive metal.

5. The method of claim 1, wherein the step of at least partially bottom-filling comprises exposing the metal silicide region to an electroless deposition solution comprising cobalt ions.

6. The method of claim 5, wherein the step of exposing comprises dipping the metal silicide region in the electroless deposition solution, flood immersing the metal silicide region in the electroless deposition solution, or spraying the electroless deposition solution on the metal silicide region.

7. The method of claim 5, wherein the step of exposing the metal silicide region to an electroless deposition solution comprises exposing the metal silicide region to an electroless deposition solution at a temperature in the range of about 20° C. to about 100° C.

8. The method of claim 7, wherein the step of exposing the metal silicide region to an electroless deposition solution at a temperature in the range of about 20° C. to about 100° C. comprises exposing the metal silicide region to an electroless deposition solution at a temperature in the range of about 40° C. to about 70° C.

9. The method of claim 1, wherein the step of depositing an insulating material overlying a metal silicide region comprise depositing an insulating material overlying a metal silicide region comprising nickel silicide.

10. The method of claim 1, wherein the step of depositing an insulating material overlying a metal silicide region comprise depositing an insulating material overlying a metal silicide region comprising cobalt silicide.

11. A method for fabricating an MOS device, the method comprising the steps of:
forming a gate electrode overlying a surface of a silicon substrate;
forming impurity-doped source and drain regions at the surface of the silicon substrate in alignment with the gate electrode;
forming metal silicide regions overlying the impurity-doped source and drain regions;
depositing an insulating material overlying the gate electrode and the metal silicide regions;
etching contact openings within the insulating material and exposing the metal silicide regions;
depositing substantially pure cobalt to partially fill the contact openings; and
depositing a conductor in the contact openings overlying the substantially pure cobalt.

12. The method of claim 11, wherein the step of depositing a conductor comprises depositing copper.

13. The method of claim 11, wherein the step of depositing a conductor comprises depositing tungsten.

14. The method of claim 11, wherein the step of depositing substantially pure cobalt comprises exposing the metal silicide regions to an electroless deposition solution comprising cobalt ions.

15. The method of claim 14, wherein the step of exposing the metal silicide regions to an electroless deposition solution comprises exposing the metal silicide regions to an electroless deposition solution at a temperature in the range of about 20° C. to about 100° C.

16. The method of claim 15, wherein the step of exposing the metal silicide regions to an electroless deposition solution at a temperature in the range of about 20° C. to about 100° C. comprises exposing the metal silicide regions to an electroless deposition solution at a temperature in the range of about 40° C. to about 70° C.

17. The method of claim 11, wherein the step of depositing an insulating material overlying the gate electrode and the metal silicide regions comprises the step of forming nickel silicide regions.

18. The method of claim 11, wherein the step of depositing an insulating material overlying the gate electrode and the metal silicide regions comprises the step of forming cobalt silicide regions.

19. A semiconductor device comprising:
an impurity-doped region disposed at a surface of a semiconductor substrate;
a metal silicide disposed on the impurity-doped region;
an insulating material overlying the impurity-doped region and having a contact opening exposing the metal silicide; and
a substantially pure cobalt portion, wherein the substantially pure cobalt portion at least partially bottom fills the contact opening.

20. The semiconductor device of claim 19, further comprising a conductive plug disposed within the contact opening overlying the substantially pure cobalt portion.
